(19) United States
(12) Patent Application Publication
(10) Pub. No.: US 2023/0360999 A1
(43) Pub. Date: Nov. 9, 2023

(54) PHASE-CHANGE HEAT DISSIPATER AND POWER MODULE

(71) Applicant: Sungrow Power Supply Co., Ltd., Hefei (CN)

(72) Inventors: Hao Zheng, Hefei (CN); Xiaohu Wang, Hefei (CN); Qiyao Zhu, Hefei (CN); Wentao Shu, Hefei (CN); Ye Yang, Hefei (CN); Nianan Pan, Hefei (CN); Jie Ding, Hefei (CN)

(73) Assignee: Sungrow Power Supply Co., Ltd., Hefei (CN)

(21) Appl. No.: 18/114,443

(22) Filed: Feb. 27, 2023

(30) Foreign Application Priority Data
May 6, 2022 (CN) 202221074073.1

(51) Int. Cl. H01L 23/427

(52) U.S. Cl. CPC H01L 23/427; H01L 25/072

(57) ABSTRACT

A phase-change heat dissipater and a power module are provided according to the present application. The phase-change heat dissipater includes least two evaporators, at least one condenser and at least two sets of heat transfer pipelines, the at least two evaporators and at least one condenser form at least two circulating heat dissipation circuits through the at least two sets of heat transfer pipelines, and a phase-change medium is filled in the at least two circulating heat dissipation circuits; and the at least two evaporators are arranged sequentially along a vertical direction. The technical solution of the present application can improve the temperature difference of the at least two evaporators and maintain the temperature uniformity of the at least two evaporators.

### CROSS REFERENCE TO RELATED APPLICATIONS

This application claims the priorities to Chinese patent application No. 202221074073.1, titled “PHASE-CHANGE HEAT DISSIPATER AND POWER MODULE”, filed with the China National Intellectual Property Administration May 6, 2022, the entire disclosure of which is hereby incorporated by reference.

### FIELD

The present application relates to the technical field of heat dissipation devices, in particular to a phase-change heat dissipater and a power module.

### BACKGROUND

Thermosyphon phase-change heat exchange is a technology with higher heat dissipation efficiency than forced air cooling. In addition, the circulating power of the internal refrigerant medium of the thermosyphon phase-change heat exchange is thermosyphon and gravity, which does not require a series of external drives, so the cost thereof is lower than that of the liquid cooling heat exchange.

In a conventional phase-change heat dissipater, a cold plate evaporator has a single chamber structure, and the temperature of the upper cold plate is higher than the temperature of the lower cold plate. When at least two layers of heat sources are provided in a vertical direction of the cold plate evaporator, the temperature of the upper heat source is higher than the temperature of the lower heat source under the same heating power due to the poor temperature uniformity in the vertical direction of the cold plate evaporator.

### SUMMARY

A phase-change heat dissipater and a power module are provided according to the present application, so as to improve the temperature difference of at least two evaporators and maintain the temperature uniformity of the at least two evaporators.

A phase-change heat dissipater is provided according to the present application, which includes at least two evaporators, at least one condenser and at least two sets of heat transfer pipelines, and the at least two evaporators and at least one condenser form at least two circulating heat dissipation circuits through the at least two sets of heat transfer pipelines, and a phase-change medium is filled in the at least two circulating heat dissipation circuits;
the at least two evaporators are arranged sequentially along a vertical direction.

In an embodiment, at least two condensers are provided, and the at least two condensers are in communication with the at least two evaporators respectively through the at least two circulating heat dissipation circuits.

In an embodiment, a condensing air duct is provided outside the at least two condensers, and the at least two condensers are arranged sequentially or side by side along an extending direction of the condensing air duct.

In an embodiment, the condensing air duct extends along the vertical direction; or
the condensing air duct extends along a horizontal direction; or
the condensing air duct extends along an inclined direction.

In an embodiment, a spacing is reserved between two adjacent evaporators.

A power module is further provided according to the present application, which includes a heat source and the phase-change heat dissipater as described above, and the heat source is in contact with the at least two evaporators of the phase-change heat dissipater.

In an embodiment, the power module further includes a housing, the heat source and the phase-change heat dissipater are arranged in the housing, a condensing air duct is formed in the housing, and the at least one condenser of the phase-change heat dissipater is located in the condensing air duct.

In an embodiment, at least two condensers are provided, and the at least two condensers are in communication with the at least two evaporators respectively through the at least two circulating heat dissipation circuits;
the at least two condensers are arranged sequentially or side by side along an extending direction of the condensing air duct.

In an embodiment, the condensing air duct extends along the vertical direction; or
the condensing air duct extends along a horizontal direction; or
the condensing air duct extends along an inclined direction

In an embodiment, the heat source is an IGBT power module and/or an IGCT power module.

In the technical solution of the present application, the at least two evaporators are independently arranged along the vertical direction, which can avoid the influence of the upper layer refrigerant being heated by the evaporation gas of the lower layer refrigerant, thus improving the temperature difference between the upper layer and lower layer evaporators, maintaining the temperature uniformity of the at least two evaporators in the vertical direction, and uniformly dissipating the heat of the heat source, which can improve the working stability of the heat source.

### BRIEF DESCRIPTION OF THE DRAWINGS

For more clearly illustrating embodiments of the present application or the technical solutions in the conventional technology, drawings referred to describe the embodiments or the conventional technology will be briefly described hereinafter. Apparently, the drawings in the following description are only some examples of the present application, and for those skilled in the art, other drawings may be obtained based on these drawings without any creative efforts.

FIG. 1 is a schematic structural view of an embodiment of a phase-change heat dissipater according to the present application;

FIG. 2 is a schematic structural view of the phase-change heat dissipater in FIG. 1 viewed from another perspective;

FIG. 3 is a schematic structural view of another embodiment of the phase-change heat dissipater according to the present application;

FIG. 4 is a schematic structural view of still another embodiment of the phase-change heat dissipater according to the present application; and

FIG. 5 is a schematic structural view of the phase-change heat dissipater in FIG. 4 viewed from another perspective.

Reference numerals are as follows:

| Serial number | Name |
|---|---|
| 10 | Evaporator |
| 20 | Condenser |
| 30 | Evaporating pipe |
| 40 | Condensing pipe |
| 50 | Heat source |

The realization of the objects, functional characteristics and advantages of the present application will be further described in conjunction with the embodiments and with reference to the drawings.

### DETAILED DESCRIPTION OF THE EMBODIMENTS

The technical solutions according to the embodiments of the present application will be described clearly and completely as follows in conjunction with the drawings in the embodiments of the present application. It is apparent that the described embodiments are only a of part of the embodiments according to the present application, rather than all of the embodiments. Based on the embodiments of the present application, all other embodiments obtained by those having ordinary skill in the art without creative work shall fall within the protection scope of the present application.

It should be noted that, all directional indicators (such as up, down, left, right, front, back . . . . . . ) in the embodiments of the present application are only used for explaining a relative position relationship and movement situation among components in a certain specific posture (as shown in the attached figures). If the specific posture changes, the directional indicators will change accordingly.

In addition, if there are descriptions related to “first”, “second” and the like in the embodiments of the present application, the “first”, “second” and the like are only used for descriptive purposes, and should not be understood as indicating or implying its relative importance or implicitly indicating the number of the indicated technical features. Therefore, the features defined with “first”, “second” or the like may include at least one of the features explicitly or implicitly. In addition, the technical solutions between the various embodiments can be combined with each other, but they must be based on the realization by a person skilled in the art. When the combination of technical solutions is contradictory or cannot be realized, it should be considered that such a combination of technical solutions does not exist, and is not within the protection scope of the present application.

A phase-change heat dissipater is provided according to the present application.

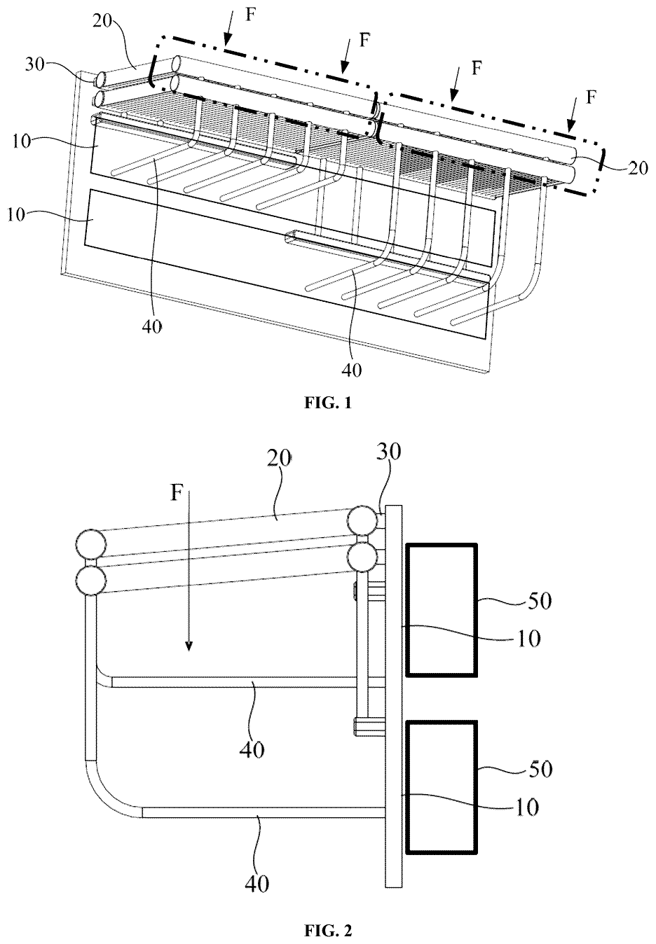

In the embodiment of the present application, as shown in FIG. 1 and FIG. 2, the phase-change heat dissipater is provided according to the present application, which includes at least two evaporators 10, at least one condenser 20 and at least two sets of heat transfer pipelines, the at least two evaporators 10 and at least one condenser 20 form at least two circulating heat dissipation circuits through the at least two sets of heat transfer pipelines, and a phase-change medium is filled in the at least two circulating heat dissipation circuits; the at least two evaporators 10 are arranged sequentially along a vertical direction.

Specifically, each heat transfer pipeline includes an evaporating pipe 30 and a condensing pipe 40, an output end of the evaporator 10 is in communication with an input end of the condenser 20 through the evaporating pipe 30, and an output end of the condenser 20 is in communication with an input end of the evaporating pipe 30 through the condensing pipe 40, so as to form a circulating heat dissipation circuit.

Int the phase-change heat dissipater, the phase-change medium inside the circulating heat dissipation circuit takes thermosiphon and gravity as the circulating power, which does not need external drive. The phase-change medium repeats the process of evaporation and condensation in the circulating heat dissipation circuit. The evaporating pipe 30 is an air passage, and the condensing pipe 40 is a liquid passage. Specifically, the phase-change medium absorbs heat in the evaporator 10 to form gas (evaporation), and the gaseous phase-change medium flows out from the output end of the evaporator 10, flows through the evaporating pipe 30, and flows into the condenser 20 from the input end of the condenser 20; the phase-change medium releases heat in the condenser 20 to form liquid (liquefaction). The liquid phase-change medium flows out from the output end of the condenser 20, flows through the condensing pipe 40, and returns to the evaporator 10 for circulation. Therefore, it is only necessary to abut the heat source 50 against the evaporator 10 and exchange heat with the external air through the condenser 20 to realize heat dissipation of the heat source 50.

It can be understood that in order to facilitate the mounting of the heat source 50 on the evaporator 10 and increase the contact area between the evaporator 10 and the heat source 50, the evaporator 10 can also be arranged into a plate structure to form a cold plate. In addition, in order to ensure the phase-change medium inside the evaporator 10 to take away the heat of the heat source 50, the liquid level of the liquid phase-change medium inside the evaporator 10 needs to be higher than or at least flush with the position of the heat source 50 (considering that if an inner cavity of the evaporator 10 is provided with a capillary structure to enable the phase-change medium to produce a siphon effect, the liquid level of the phase-change medium can also be slightly lower than the heat source 50).

The phase-change heat dissipater can be applied to a power module, specifically an inverter, and the inverter includes a power module. The power module generates large heat when working, and is one of the heat sources 50 of the inverter. The phase-change heat dissipater can be mounted in the inverter to dissipate heat from the power components.

In the solution that the at least two evaporators 10 are common in one cavity, the temperature of the upper layer phase-change medium is heated due to the rise of bubbles generated by the evaporation of the lower layer phase-change medium, which causes the temperature of the upper layer evaporator 10 to be higher than the temperature of the lower layer evaporator 10, affects the heat dissipation efficiency of the upper layer heat source 5 by the upper layer phase-change medium, and causes the temperature difference between the upper and lower layers evaporators 10. The technical solution of the present application adopts that the at least two evaporators 10 are independently arranged along the vertical direction, which can avoid the influence of the upper layer phase-change medium being heated by the evaporating gas of the lower layer phase-change medium, thus improving the temperature difference between the upper layer and lower layer evaporators 10, maintaining the temperature uniformity of the at least two evaporators 10 in the vertical direction, uniformly dissipating the heat of the heat source 50, and improving the working stability of the heat source 50.

In an embodiment, at least two condensers 20 are provided, and the least two condensers 20 are in communication with the at least two evaporators 10 respectively through the at least two circulating heat dissipation circuits.

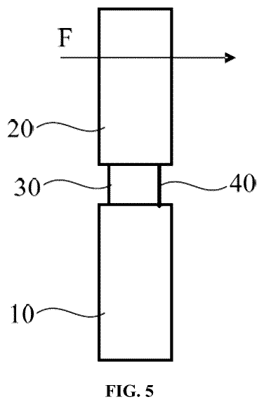

For the phase-change heat dissipater according to the present application, one evaporator 10 corresponds to one condenser 20 to form a circulating heat dissipation circuit (as shown in FIG. 1 and FIG. 2); alternatively, one evaporator 10 may correspond to multiple condensers 20, that is, multiple circuits return to the evaporator 10 (as shown in FIG. 4 and FIG. 5) during liquefaction of the phase-change medium; alternatively, one condenser 20 may correspond to multiple evaporators 10, that is, multiple flow passages of the evaporators 10 can ensure that the phase-change medium of the evaporators 10 evaporates completely, and the gaseous phase-change medium flows to the condenser 20 before being liquefied and flowed back. The above multiple structures can improve the evaporation or liquefaction efficiency of the phase-change medium in the inner cavity of the evaporator 10 to varying degrees, thereby improving the heat dissipation efficiency and heat dissipation performance of the whole phase-change heat dissipater, and meeting the heat dissipation requirements of various condensing air ducts of the whole machine.

In an embodiment, a condensing air duct is provided outside the at least two condensers 20 (F in the figure is an airflow direction of the condensing air duct), and the at least two condensers 20 are arranged sequentially or side by side along an extending direction of the condensing air duct.

The condensing air duct is configured to dissipate heat from the at least two condensers 20 in the circulating heat dissipation circuit, so that the gaseous phase-change medium in the condenser 20 can be converted into a liquid phase-change medium by the heat exchange with the external air and returns to the evaporator 10. The at least two condensers 20 can be arranged sequentially or side by side along the direction of the condensing air duct.

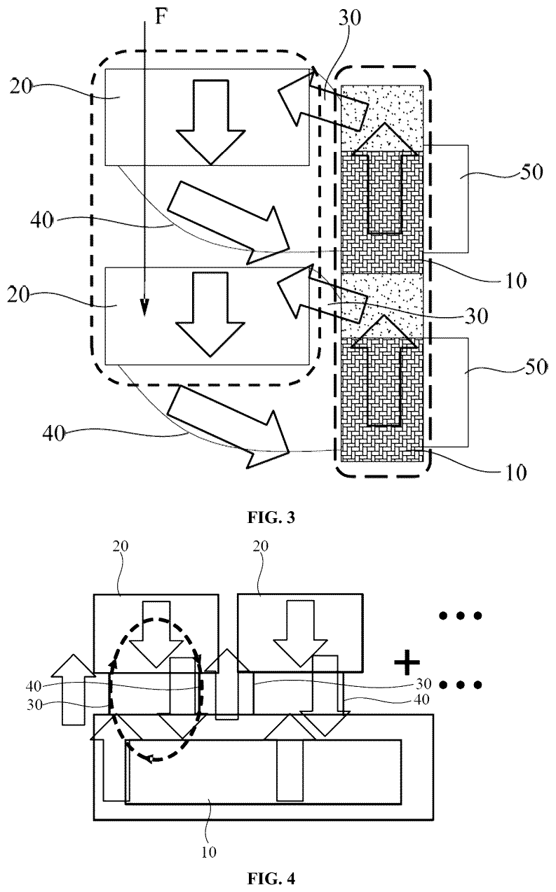

When the at least two condensers 20 in the circulating heat dissipation circuit are arranged sequentially along the direction of the condensing air duct (as shown in FIG. 3), the external cold air blows the first condenser 20 first, then the formed hot air blows the second condenser 20, and so on. Since the temperatures of air inlet ends of the second stage condenser 20 and the subsequent condenser 20 are relatively high, and part of the air volume is lost after the formed hot air passing the first stage condenser 20, the heat exchange efficiency of the second circulating heat dissipation circuit is low, which easily causes the temperature of the second evaporator 10 being higher than the temperature of the first evaporator 10, thus causing the temperature of the second heat source 50 to be high.

When the at least two condensers 20 in the circulating heat dissipation circuit are arranged side by side (as shown in FIG. 1 and FIG. 2), the external cold air reaches the first condenser 20 and the second condenser 20 simultaneously, which can ensure that the intake air of the first condenser 20 and the second condenser 20 are fresh air, so as to ensure the difference in the heat exchange of the first condenser 20 and the second condenser 20 to be small, and ensure the temperature difference of the evaporators 10 in the vertical direction to be small.

In an embodiment, the condensing air duct extends along the vertical direction; or the condensing air duct extends along a horizontal direction; or the condensing air duct extends along an inclined direction.

In this embodiment, the direction of the condensing air duct may be a vertical direction, a horizontal direction or an inclined direction (that is, a direction forming an angle with the horizontal plane), which can be adjusted according to the layout of the condensers 20. For example, when the at least two condensers 20 in the circulating heat dissipation circuit are arranged side by side, and the condensers 20 in the circulating heat dissipation circuit are arranged along the horizontal direction, the direction of the condensing air duct may be the vertical direction (as shown in FIG. 1 and FIG. 2), or the direction of the condensing air duct may be the vertical direction may be the horizontal direction (as shown in FIG. 4 and FIG. 5); when the condensers 20 are arranged along the inclined direction forming an angle with the horizontal plane, the direction of the condensing air duct is perpendicular to the inclined direction.

Simultaneously, the airflow direction of the condensing air duct can also be arranged according to the actual needs. Taking the condensing air duct along the vertical direction as an example, the airflow direction can be from bottom to top or from top to bottom, which is not limited herein.

In an embodiment, referring to FIG. 1 and FIG. 2, a spacing is reserved between two adjacent evaporators 10.

Generally, the upper layer and lower layer heat sources 50 abut against the two evaporators 10 in a one-to-one correspondence. In the solution that the at least two evaporators 10 share a cavity, in order to ensure that the phase-change medium in the inner cavity of the evaporator 10 can reach the position of the upper layer heat source 50, it is necessary to charge the phase-change medium to the position of the upper layer heat source 50, so that the blank space of the evaporator 10 between the upper layer and lower layer heat sources 50 (the spacing between the upper layer and lower layer heat sources 50) of the evaporator 10 is full of the phase-change medium, but the phase-change medium here does not participate in heat exchange, which leads to a large filling amount of the phase-change medium; certainly, the amount of the phase-change medium can be reduced by reducing the volume of the inner cavity of the evaporator 10 by a variable cross section, which may affect the flow resistance of the inner cavity. The technical solution of the present application adopts that the upper and lower evaporators 10 are independently arranged and the two sets of circulating heat dissipation circuits operate separately without affecting each other. After the evaporators 10 of the two sets of circulating heat dissipation circuits corresponding to the upper layer and lower layer heat sources 50 are arranged separately, the consumption of the phase-change medium of the whole phase-change heat dissipater can be reduced and the cost can be reduced.

A power module is further provided according to the present application, which includes at least two heat sources 50 and the phase-change heat dissipater as described above, and the specific structure of the phase-change heat dissipater refers to the above embodiments. Since the power module adopts all the technical solutions of the above embodiments, it at least has all the technical effects brought by the technical solutions of the above embodiments, and is not described herein. The at least two heat sources 50 are arranged in contact with the at least two evaporators 10 of the phase-change heat dissipater.

In an embodiment, the power module further includes a housing, the at least two heat sources 50 and the phase-change heat dissipater are arranged in the housing, a condensing air duct is formed in the housing, and the at least one condenser 20 of the phase-change heat dissipater is located in the condensing air duct.

After the phase-change medium in the evaporators 10 of the phase-change heat dissipater absorbs heat from the heat source 50, the gaseous phase-change medium flows into the condenser 20 of the phase-change heat dissipater and exchanges heat with the condenser 20 by the external cold air entering the condensing air duct, so that the gaseous phase-change medium is liquefied to form a liquid phase-change medium and returns to the evaporators 10, thereby improving the heat dissipation efficiency of the phase-change heat dissipater. Moreover, a fan can be provided in the condensing air duct to drive the airflow in the condensing air duct to form forced air cooling, which can further improve the heat dissipation efficiency of the phase-change heat dissipater.

In an embodiment, at least two condensers 20 are provided, and the at least two condensers 20 are in communication with the at least two evaporators 10 respectively through the at least two circulating heat dissipation circuits; the at least two condensers 20 are arranged sequentially or side by side along an extending direction of the condensing air duct.

When the at least two condensers 20 in the circulating heat dissipation circuit are arranged sequentially along the direction of the condensing air duct (as shown in FIG. 2), the external cold air blows the first condenser 20 first, then the formed hot air blows the second condenser 20, and so on. Since the temperatures of air inlet ends of the second stage condenser 20 and the subsequent condenser 20 are relatively high, and part of the air volume is lost after the first stage condenser 20, the heat exchange efficiency of the second circulating heat dissipation circuit is low, which easily leads to the temperature of the second evaporator 10 being higher than the temperature of the first evaporator 10, thus causing the temperature of the second heat source 50 to be high.

When the at least two condensers 20 in the circulating heat dissipation circuit are arranged side by side (as shown in FIG. 1 and FIG. 2), the external cold air reaches the first condenser 20 and the second condenser 20 simultaneously, which can ensure that the intake air of the first condenser 20 and the second condenser 20 are fresh air, so as to ensure that the difference in the heat exchange of the first condenser 20 and the second condenser 20 is small, and ensure that the temperature difference of the evaporators 10 in the vertical direction is small.

In an embodiment, the condensing air duct extends along the vertical direction; or the condensing air duct extends along a horizontal direction; or the condensing air duct extends along an inclined direction

In this embodiment, the direction of the condensing air duct may be a vertical direction, a horizontal direction or an inclined direction (that is, a direction forming an angle with the horizontal plane), which can be adjusted according to the layout of the condensers 20. For example, when the at least two condensers 20 in the circulating heat dissipation circuit are arranged side by side, and the condensers 20 in the circulating heat dissipation circuit are arranged along the horizontal direction, the direction of the condensing air duct may be the vertical direction (as shown in FIG. 1 and FIG. 2), or the direction of the condensing air duct may be the vertical direction may be the horizontal direction (as shown in FIG. 4 and FIG. 5); when the condensers 20 are arranged along the inclined direction forming an angle with the horizontal plane, the direction of the condensing air duct is perpendicular to the inclined direction.

In an embodiment, the heat source 50 is an IGBT power module and/or an IGCT power module.

For the power module, the IGBT (Insulated Gate Bipolar Transistor) power module and the IGCT (Integrated Gate Converter Thyristor) power module are the electronic components with large heat generation in the power module. When the phase-change heat dissipater is applied to the power module, the heat source 50 such as the IGBT power module and the IGCT power module can be effectively cooled by the phase-change heat dissipater, so as to improve the working stability of the heat source 50.

The above are only preferred embodiments of the present application, and do not limit the scope of the present disclosure. Under the concept of the present application, any equivalent structural transformation made by using the content of description and drawings of the present application e, or direct/indirect applications in other related technical fields, are included in the protection scope of the present application.

1. A phase-change heat dissipater, comprising at least two evaporators, at least one condenser and at least two sets of heat transfer pipelines, wherein the at least two evaporators and at least one condenser form at least two circulating heat dissipation circuits through the at least two sets of heat transfer pipelines, and a phase-change medium is filled in the at least two circulating heat dissipation circuits;
wherein the at least two evaporators are arranged sequentially along a vertical direction.

2. The phase-change heat dissipater according to claim 1, wherein at least two condensers are provided, and the at least two condensers are in communication with the at least two evaporators respectively through the at least two circulating heat dissipation circuits.

3. The phase-change heat dissipater according to claim 2, wherein a condensing air duct is provided outside the at least two condensers, and the at least two condensers are arranged sequentially or side by side along an extending direction of the condensing air duct.

4. The phase-change heat dissipater according to claim 3, wherein the condensing air duct extends along the vertical direction; or
the condensing air duct extends along a horizontal direction; or
the condensing air duct extends along an inclined direction.

5. The phase-change heat dissipater according to claim 1, wherein a spacing is reserved between two adjacent evaporators.

6. A power module, comprising a heat source and the phase-change heat dissipater according to claim 1, wherein the heat source is arranged in contact with the at least two evaporators of the phase-change heat dissipater.

7. The power module according to claim 6, wherein the power module further comprises a housing, the heat source and the phase-change heat dissipater are arranged in the housing, a condensing air duct is formed in the housing, and the at least one condenser of the phase-change heat dissipater is located in the condensing air duct.

8. The power module according to claim 7, wherein at least two condensers are provided, and the at least two condensers are in communication with the at least two evaporators respectively through the at least two circulating heat dissipation circuits;
the at least two condensers are arranged sequentially or side by side along an extending direction of the condensing air duct.

9. The power module according to claim 8, wherein the condensing air duct extends along the vertical direction; or
the condensing air duct extends along a horizontal direction; or
the condensing air duct extends along an inclined direction

10. The power module according to claim 6, wherein the heat source is an IGBT power module and/or an IGCT power module.
